(19) United States
(12) Patent Application Publication
(10) Pub. No.: US 2015/0241603 A1
(43) Pub. Date: Aug. 27, 2015

(54) ANTI-REFLECTION STRUCTURE, IMPRINT MOLD, METHOD FOR PRODUCING ANTI-REFLECTION STRUCTURE, METHOD FOR PRODUCING IMPRINT MOLD, AND DISPLAY DEVICE

(71) Applicant: Sharp Kabushiki Kaisha, Osaka-shi, Osaka (JP)

(72) Inventors: Akiyoshi Fujii, Osaka-shi (JP); Tokio Taguchi, Osaka-shi (JP)

(73) Assignee: SHARP KABUSHIKI KAISHA, Osaka-shi, Osaka (JP)

(21) Appl. No.: 14/409,428

(22) PCT Filed: Jun. 14, 2013
(86) PCT No.: PCT/JP2013/066427

§ 371 Date: Dec. 18, 2014

(30) Foreign Application Priority Data
Jun. 22, 2012 (JP) 2012-141316

(51) Int. Cl. G02B 1/11; G03F 7/00

(52) U.S. Cl. CPC G02B 1/11; G03F 7/0005

(57) ABSTRACT

Disclosed are an anti-reflection structure, an imprint mold, methods for producing them and a display device capable of achieving appropriate visibility by forming regions different in reflection characteristics mixed in a film including a moth-eye structure, and sufficiently reducing reflection and sufficiently improving transmittance by the moth-eye structure. The anti-reflection structure includes a surface with an uneven structure composed of a transparent body and includes protrusions, the width between the tops of any pair of the adjacent protrusions being equal to or shorter than visible light wavelengths, the anti-reflection structure including a first region including a surface with the uneven structure, and a second region including a surface with a structure composed of a transparent body, the structure being different from the uneven structure and the second region in a plan view having a shape forming at least one selected from the group consisting of characters, symbols, and graphics.

### TECHNICAL FIELD

The present invention relates to an anti-reflection structure, an imprint mold, methods for producing them, and a display device. The present invention specifically relates to an anti-reflection structure and an imprint mold which include a surface with a moth-eye structure, method for producing them, and a display device including a display surface with a moth-eye structure.

### BACKGROUND ART

Flat panel display (FPD) technology has been greatly advanced, and display devices such as liquid crystal TVs and mobile devices (smartphones, tablets) including an FPD have become popular these days. FPDs are often used in bright places as is well exemplified by the application to TVs and mobile devices. Thus, good visibility of FPDs is required in not only dark places but bright places as well.

An FPD is a display device generally produced using a glass substrate. Since light reflects on the surface of the display device in bright places, the reflected light problematically hinders the view of images. In the case of conventional FPDs, as techniques to reduce the reflection on the surface, low reflection (LR) treatment and antiglare (AG) treatment have been performed.

Meanwhile, as a technology to improve visibility in bright places other than the LR treatment and the AG treatment, an increasing attention has been paid to moth-eye structures, which provide great anti-reflection effects without using the light interference technique. For forming a moth-eye structure on a surface of a product to which anti-reflection treatment is performed, an uneven pattern at intervals of not more than a wavelength of light (for example, 400 nm or less), which is finer than the pattern to be formed by AG treatment, is arranged without any space therebetween. Thereby, changes of the refractive index at the border between the outside (air) and the film surface are artificially made sequential. As a result, the product with the moth-eye structure can transmit almost all light regardless of the refractive index interface so that almost all the light reflection on the surface of the product can be avoided.

For example, an anti-reflection film, which reduces reflection of visible light on a surface of a substrate by being mounted on the substrate, includes a wavelength dispersion structure for applying first wavelength dispersion to visible light transmitting through the anti-reflection film, and contains a wavelength dispersion material for applying second wavelength dispersion to the visible light transmitting through the anti-reflection film. Visible light transmitted through the anti-reflection film has flat transmission wavelength dispersion in a visible light region (see, for example, Patent Literature 1).

As a method for forming a moth-eye structure on a surface of a display device, a method including firstly preparing a mold with a fine uneven pattern; forming a film, on the surface of the display device, to which the uneven pattern is to be imprinted; and then pressing the mold to the surface of the film to imprint the uneven pattern of the mold to the surface of the film (see, for example, Patent Literatures 2, 3, and 5 to 7), or a method including forming an uneven pattern on a surface of a film by etching the surface using a metal film as a mask (see, for example, Patent Literature 4), or other methods may be exemplified. As a method for forming an uneven pattern of a mold, a method including anodization and etching, electron beam lithography, and other methods may be exemplified.

### CITATION LIST

### Patent Literature

Patent Literature 1: WO 2010/032610
Patent Literature 2: JP 2004-205990 A
Patent Literature 3: JP 2004-287238 A
Patent Literature 4: JP 2001-272505 A
Patent Literature 5: JP 2002-286906 A
Patent Literature 6: JP 2003-43203 A
Patent Literature 7: WO 2006/059686

### SUMMARY OF INVENTION

### Technical Problem

In the invention disclosed in Patent Literature 1, wavelength dispersion characteristics of a moth-eye structure are compensated by an underlying film so that neutral characteristics are achieved (see, for example, one example of a schematic cross-sectional view of a conventional anti-reflection film [FIG. 34]). This designs the concept of the compensation based on the wavelength dispersion characteristics of a moth-eye structure. However, in the above prior arts, attention is paid only on low reflection treatment on a surface of a display device, and techniques for performing display at part of the display device or the like have not devised or examined.

For example, it is presumed that if a character such as a logo (logotype), symbol, or graphic can be formed on a moth-eye surface, and displayed using characteristics of a moth-eye structure, such a structure can be used in various purposes.

In order to perform such display, when an opaque portion is partially formed on the moth-eye surface, for example, by putting an ink i in the moth-eye surface by printing, the opaque portion loses the moth-eye function, and has increased surface reflection and reduced transmittance (a region 1015 in FIG. 33). If such a moth-eye structure is placed on a front face of a display device, display images may not be seen or hardly seen.

The moth-eye structure remarkably reduces surface reflection. Therefore, when a film including the moth-eye structure is partially filled with an opaque component such as a printing ink, such a filled portion loses a moth-eye effect, and has increased reflection and reduced transmittance, and is therefore distinctly visible. That is, in FIG. 33, a moth-eye portion (a region 1013) highly transmits light and less reflects light on the surface, on the other hand, on a portion where the moth-eye structure is filled with an ink i or the like (the region 1015), much light is directly reflected and dispersed, and therefore is less transmitted. As a result, the region 1015 is more distinctly visible than the region 1013. Accordingly, there is a demand for achieving display not hindering display of a display device by, for example, making a character such as a logo, symbol, or graphic to be recognized not always, but under a certain condition.

The present invention has been made in view of the above-described state of the art. The present invention has an object to provide an anti-reflection structure, an imprint mold, methods for producing them and a display device capable of achieving appropriate visibility by forming regions different in reflection characteristics mixed in a film including a moth-eye structure, and sufficiently reducing reflection and sufficiently improving transmittance by the moth-eye structure.

### Solution to Problem

The present inventors have performed various studies on an anti-reflection film including a moth-eye structure capable of reducing light reflected on a surface of a display device, in which a moth-eye region having different characteristics from other moth-eye regions is partially formed, that is, regions different in reflection characteristics are formed mixed in the film (positively forming regions). Thereby, the shape of the moth-eye region having different characteristics from other moth-eye regions can be used to represent a logo or the like, or visibility can be enhanced by a little reflection with color due to the moth-eye structure. The present inventors have noted that, when regions different in reflection characteristics are partially mixed, a specific region having different characteristics from other regions is distinctly viewed from the other regions therearound including a moth-eye structure with low reflection.

The present inventors have performed various studies for solving such problems, and have found that, wavelength dispersion of reflection light in a portion having a shape that forms a character such as a logo, symbol, or graphic is favorably changed from other portions therearound by changing the heights or the shapes of protrusions and depressions of the moth-eye structure of the portion, or by making the portion flat without forming the moth-eye structure.

In particular, a portion having a shape that forms a character such as a logo, symbol, or graphic including protrusions and depressions of the moth-eye structure with a height or a shape different from other portions therearound is favorably distinctly viewed because a little reflection on the surface of the portion is colored. In this case, since the moth-eye structure is present also in the portion having a shape that forms a logo or the like, the reflectance at the portion does not extremely increase. Therefore, a logo or the like is less visible when viewed from the front, but is faintly visible when viewed from an angle because of its different reflection effects of the moth-eye structure. As described above, in the moth-eye region having moth-eye function where regions different in reflection characteristics are mixed, a character such as a logo, symbol, or graphic is visually recognized not always, but only under certain conditions. As a result, display of a display device is not hindered.

FIG. 5 illustrates that the height of the moth-eye structure is partially low. The wavelength dispersion in such a portion, i.e. in a region 15, appears more reddish than that in a region 13 including a higher moth-eye structure because reflection of visible light in a red region increases. Here, the reflectance of the region 15 is low because of the effect of the moth-eye structure therein. Therefore, the light transmittance is not extremely reduced, or scattering and reflection of light are not extremely increased unlike that illustrated in FIG. 33.

Thus, the above-described problems have been solved, leading to completion of the present invention.

The present invention is different from the invention disclosed in Patent Literature 1 in that regions including a moth-eye pattern different in wavelength dispersion are positively formed. As disclosed in Patent Literature 1, a layer may be formed below the anti-reflection film or the like of the present invention. Further, the present invention is capable of preferably changing tinge, which has not conventionally been disclosed.

That is, according to a first aspect of the present invention, there is provided an anti-reflection structure including: a surface with an uneven structure that is composed of a transparent body and includes protrusions, the width between the tops of any pair of the adjacent protrusions being equal to or shorter than visible light wavelengths, the anti-reflection structure including a first region including a surface with the uneven structure, and a second region including a surface with a structure that is composed of a transparent body, the structure being different from the uneven structure in the first region, the second region in a plan view having a shape that forms at least one selected from the group consisting of characters, symbols, and graphics.

Use of the anti-reflection structure provides the following advantages (1) to (3).

(1) An advertisement, logo, sign, or the like is displayed when a display device is not in a displayed state (ON) as background. For example, a moth-eye sheet placed on the front of a display device or the like can display an advertisement or logo when the display device is in a displayed state (OFF). When a moth-eye pattern is attached to glass or the like, surface reflection is extremely lowered, and the glass is therefore less visible. Therefore, a collision accident may be caused. If reflection partially occurs, a wall is visually recognized so that such an accident can be prevented.

(2) When a portion having a shape that forms a character, symbol, or graphic includes a moth-eye structure, excellent appearance is provided. For example, when a portion having a shape that forms a character, symbol, or graphic includes a moth-eye structure, visibility through the moth-eye structure is not extremely degraded. Therefore, a character, symbol, or graphic is not too distinct and is not annoying. Further, reflection characteristics of a portion having a shape that forms a character, symbol, or graphic can be changed by changing the moth-eye structure, thereby changing tinge of the portion. Therefore, such an anti-reflection structure can be used for decorative applications. Further, when the anti-reflection structure is used at a dull and dark display portion of a display device such as TVs in an undisplayed state, a color tone is emphasized to provide extensive decorative effects. Such a portion having a shape that forms a character, symbol, or graphic is not distinctly visible, and may be arranged randomly on a moth-eye sheet.

(3) Producing is easy. For example, if an imprint mold (mold) including a predetermined structure capable of giving a character, symbol, or graphic pattern is produced, the anti-reflection structure can be prepared by imprinting the pattern of the mold.

The anti-reflection structure of the present invention includes a surface with a fine uneven structure (hereinafter, also referred to as a first uneven structure or moth-eye structure) that includes protrusions in which a width (pitch) between the tops of any pair of the adjacent protrusions is equal to or shorter than visible light wavelengths. The expression “equal to or shorter than visible light wavelengths” herein means 380 nm or less, which is the lower limit in the general visible light wavelength range. The width between the tops is preferably 300 nm or less, and more preferably 200 nm or less.

The second region in the anti-reflection structure of the present invention is usually bounded by the first region, and has a shape that forms at least one selected from the group consisting of characters, symbols, and graphics. Such a character, symbol, or graphic is favorably visible. The character, symbol, or graphic may not be visible when the anti-reflection structure is viewed in plan, but may be visible when the anti-reflection structure is viewed from an angle. For example, the second region that is in contact with and surrounded by the first region has a shape that forms at least one selected from the group consisting of characters, symbols, and graphics.

The phrase “the second region in a plan view having a shape that forms at least one selected from the group consisting of characters, symbols, and graphics” herein usually means that the shape of the second region bounded by the first region has a shape that forms at least one selected from the group consisting of characters, symbols, and graphics. The characters refer to codes used to represent languages, the symbols refer to codes other than characters. The graphics refer to portions having a shape, other than codes, defined by the outline of the second region.

In the anti-reflection structure of the present invention, the second region is preferably intended to be used to enhance visibility for calling attention.

For example, an accident such as collision with walls can be prevented by providing an anti-reflection film with such a structure to the walls to allow the walls to be recognized.

In the anti-reflection structure of the present invention, the second region is preferably used as a logo and/or an advertisement.

In the anti-reflection structure of the present invention, the second region is preferably recognized by color difference between the second region and the first region around the second region.

In the anti-reflection structure of the present invention, the anti-reflection structure may be an anti-reflection film that is composed of a transparent resin. In the anti-reflection film, the uneven structure in the first region and the structure in the second region are usually composed of a transparent resin. Examples of the transparent resin include resins which cure under certain conditions, such as photocurable resins and thermosetting resins. These resins are preferably used to form a high-definition moth-eye structure.

The anti-reflection film is, for example, thinly formed on a plane surface of a base. Examples of the base on which the anti-reflection film is to be formed include members forming an outermost surface of the display device, such as a polarizing plate, an acrylic protective plate, a hard coat layer placed on the surface of the polarizing plate, and an antiglare layer placed on the surface of the polarizing plate. Disposing the anti-reflection film on an observation side of the display device as mentioned makes it possible to blur the reflection of image caused by the reflected light so that the image is obscured.

The preferred embodiments of the anti-reflection structure of the present invention include that the structure in the second region is an uneven structure including protrusions, the width between the tops of any pair of the adjacent protrusions being equal to or shorter than visible light wavelengths. The uneven structure in the first region and the uneven structure in the second region may be different in height or shape. The second region is preferably displayed as a character, symbol, or graphic by using a little reflection with color due to the moth-eye structure.

A protrusion of the uneven structure in the second region is preferably different in height from a protrusion of the uneven structure in the first region. Further, the uneven structure in the second region is preferably different in shape from the uneven structure in the first region. The difference in shape between the uneven structures includes a difference in the height of a protrusion, a difference in the pitch between protrusions, and a difference in the inclination of a protrusion, and includes combination of these differences.

The preferred embodiments of the anti-reflection structure of the present invention include that the structure in the second region is not an uneven structure including protrusions, the width between the tops of any pair of the adjacent protrusions being equal to or shorter than visible light wavelengths.

The structure in the second region differs from the uneven structure in the first region in that the structure in the second region has, for example, a flat shape or an uneven structure including protrusions in which the width between the tops of any pair of the adjacent protrusions is longer than visible light wavelengths. A flat shape is preferred, for example. Examples of the flat shape include a shape in which no uneven structure (moth-eye structure) that is composed of a transparent resin and includes protrusions, the width between the tops of any pair of the adjacent protrusions being equal to or shorter than visible light wavelengths, is formed in a production process; and a shape in which an uneven structure (moth-eye structure) that is composed of a transparent resin and includes protrusions, the width between the tops of any pair of the adjacent protrusions being equal to or shorter than visible light wavelengths, is formed in a production process, but a transparent resin fills the uneven structure to make the surface flat. Both shapes are preferred.

According to a second aspect of the present invention, there is provided a method for producing an anti-reflection structure including a surface with an uneven structure that is composed of a transparent body and includes protrusions, the width between the tops of any pair of the adjacent protrusions being equal to or shorter than visible light wavelengths, the method including: forming a first region including a surface with the uneven structure and a second region including a surface with a structure that is composed of a transparent body, the structure being different from the uneven structure in the first region, the second region in a plan view having a shape that forms at least one selected from the group consisting of characters, symbols, and graphics.

The method for producing an anti-reflection structure of the present invention preferably includes, after forming the uneven structure, partially transforming the formed uneven structure. The transforming refers to the filling of a part or whole of the uneven structure with an additional transparent resin or the change of the height or the shape of the uneven structure by changing the conditions and/or the number of treatments for forming the uneven structure. The aforementioned uneven structure partially transformed is the second region according to the present invention.

The method for producing an anti-reflection structure of the present invention may be for producing an anti-reflection film that is composed of a transparent resin. In the anti-reflection film produced by the method for producing an anti-reflection film, usually, an uneven structure in the first region and a structure in the second region are composed of a transparent resin.

Preferred embodiments of the anti-reflection structures produced by the method of the present invention are the same as the preferred embodiments of the anti-reflection structures of the present invention.

According to a third aspect of the present invention, there is provided an imprint mold including: a surface with an uneven structure including protrusions, the width between the tops of any pair of the adjacent protrusions being equal to or shorter than visible light wavelengths, the imprint mold including a first region including a surface with the uneven structure and a second region including a surface with a structure that is different from the uneven structure in the first region, the second region in a plan view having a shape that forms at least one selected from the group consisting of characters, symbols, and graphics.

According to a fourth aspect of the present invention, there is provided a method for producing an imprint mold including a surface with an uneven structure including protrusions, the width between the tops of any pair of the adjacent protrusions being equal to or shorter than visible light wavelengths, the method including: a first step of forming a metal film on a base; and a second step of forming, on a surface of the metal film, a first region including a surface with the uneven structure and a second region including a surface with a structure that is different from the uneven structure in the first region, the second region in a plan view having a shape that forms at least one selected from the group consisting of characters, symbols, and graphics.

In the method of the present invention, the second step preferably includes forming holes at regular intervals in the metal film at least by anodization.

In the method of the present invention, the second step preferably includes separately forming the first region and the second region by changing the number of anodization and/or etching and/or the processing time of anodization and/or etching.

The method preferably includes separately forming the first region and the second region by anodization and/or etching using a mask.

According to a fifth aspect of the present invention, there is provided a display device including: on a display surface, a transparent body including a surface with an uneven structure including protrusions, the width between the tops of any pair of the adjacent protrusions being equal to or shorter than visible light wavelengths, the transparent body including a first region including a surface with the uneven structure and a second region including a surface with a structure that is different from the uneven structure in the first region, the second region in a plan view having a shape that forms at least one selected from the group consisting of characters, symbols, and graphics. In the display device of the present invention, the uneven structure in the first region and the structure in the second region are preferably composed of a transparent resin.

The display device of the present invention preferably includes the anti-reflection structure of the present invention or the anti-reflection structure obtained by the method for producing the anti-reflection structure of the present invention on a display surface. For example, it is preferred that the anti-reflection structure of the present invention is placed on the front face (a face on the viewer side) of the display device or attached to the display device. Further, the display device of the present invention may have a function of the anti-reflection structure of the present invention on the front face.

The display device of the present invention may preferably be a liquid crystal display (LCD) device, a plasma display panel (PDP), or an electroluminescence (EL) display. The electroluminescence display is preferably an organic electroluminescence display (OELD). The present invention is particularly preferably used for a display device in which a light reflective material, such as an electrode and wirings, is used. According to the display device of the present invention, better effects of reducing reflection at a display surface (surface of a display panel facing outward) and the inside of the display device can be obtained.

In the display device of the present invention, the second region is preferably used as a logo and/or an advertisement when the display device is in an undisplayed state.

Preferred embodiments of the uneven structure or the like of the display device of the present invention are the same as the preferred embodiments of the uneven structure or the like of the anti-reflection structure of the present invention.

The configurations of the anti-reflection structure, the imprint mold, the methods for producing them, and the display device of the present invention are not especially limited as long as the above-mentioned components are essentially included. The anti-reflection structure, the imprint mold, the methods for producing them, and the display device of the present invention may or may not include other components. For example, although the anti-reflection structure, the imprint mold, the methods for producing them, and the display device of the present invention are required to include an uneven structure including protrusions in which the width (pitch) between the tops of any pair of the adjacent protrusions is equal to or shorter than visible light wavelengths, the height from the top to the bottom may be equal to or less than, or more than visible light wavelengths.

The embodiments can be suitably combined with each other without departing from the scope of the present invention.

### Advantageous Effects of Invention

According to the present invention, while regions different in reflection characteristics are formed mixed in a structure including a moth-eye structure, reflection is sufficiently reduced and transmittance is sufficiently improved by the moth-eye structure.

### BRIEF DESCRIPTION OF DRAWINGS

FIG. 1 is a plan view schematically illustrating an anti-reflection film of Embodiment 1.

FIG. 2 is a cross-sectional view schematically illustrating protrusions of different heights in a moth-eye structure.

FIG. 3 is a graph of reflectance (%) against wavelength (nm) of light on each of the protrusions illustrated in FIG. 2.

FIG. 4 is a cross-sectional view schematically illustrating a moth-eye structure of an anti-reflection film of Embodiment 1.

FIG. 5 is a cross-sectional view schematically illustrating a moth-eye structure of an anti-reflection film of Embodiment 1.

FIG. 6 is a plan view schematically illustrating an anti-reflection film of a modified example of Embodiment 1.

FIG. 7 is an example of a cross-sectional view schematically illustrating an anti-reflection film of a modified example of Embodiment 1.

FIG. 8 is an example of a cross-sectional view schematically illustrating an anti-reflection film of a modified example of Embodiment 1.

FIG. 9 is a cross-sectional view schematically illustrating the anti-reflection film illustrated in FIG. 7 which is exposed to light entered almost vertically to the film.

FIG. 10 is a cross-sectional view schematically illustrating the anti-reflection film illustrated in FIG. 7 which is exposed to light entered at an angle to the film.

FIG. 11 is a graph of reflectance (%) against wavelength (nm) of light when light is entered to the region A illustrated in FIG. 9 at an incident angle of 5° from the surface normal and light is entered to the region A illustrated in FIG. 10 at an incident angle of 60° from the surface normal.

FIG. 12 is a graph of reflectance (%) against wavelength (nm) of light when light is entered to the region B illustrated in FIG. 9 at an incident angle of 5° from the surface normal and when light is entered to the region B illustrated in FIG. 10 at an incident angle of 60° from the surface normal.

FIG. 13 is a cross-sectional view schematically illustrating the anti-reflection film illustrated in FIG. 8 which is exposed to light entered almost vertically to the film.

FIG. 14 is a cross-sectional view schematically illustrating the anti-reflection film illustrated in FIG. 8 which is exposed to light entered at an angle to the film.

FIG. 15 is a graph of reflectance (%) against wavelength (nm) of light when light is entered at different incident angles to the region A illustrated in FIGS. 13 and 14.

FIG. 16 is a graph of reflectance (%) against wavelength (nm) of light when light is entered at different incident angles to the region B illustrated in FIGS. 13 and 14.

FIG. 17 is a schematic view of an imprint mold of Embodiment 2.

FIG. 18 is a cross-sectional view schematically showing a production process flow of an imprint mold of Embodiment 2.

FIG. 19 is a photograph of the cross section of an imprint mold of Embodiment 2.

FIG. 20 is a photograph of the cross section of an imprint mold of Embodiment 2.

FIG. 21 is a cross-sectional view schematically illustrating an imprint mold of the first modified example of Embodiment 2 during a production process.

FIG. 22 is a cross-sectional view schematically illustrating an imprint mold of the first modified example of Embodiment 2.

FIG. 23 is a cross-sectional view schematically illustrating an imprint mold of the second modified example of Embodiment 2 during a production process.

FIG. 24 is a cross-sectional view schematically illustrating an imprint mold of the second modified example of Embodiment 2.

FIG. 25 is a cross-sectional view schematically illustrating an anti-reflection film of the third modified example of Embodiment 2 during a production process.

FIG. 26 is a cross-sectional view schematically illustrating an anti-reflection film of the third modified example of Embodiment 2.

FIG. 27 is a cross-sectional view schematically illustrating an imprint mold of the fourth modified example of Embodiment 2 during a production process.

FIG. 28 is a cross-sectional view schematically illustrating an imprint mold of the fourth modified example of Embodiment 2.

FIG. 29 is a cross-sectional view schematically illustrating an imprint mold of the fifth modified example of Embodiment 2 during a production process.

FIG. 30 is a cross-sectional view schematically illustrating an imprint mold of the fifth modified example of Embodiment 2.

FIG. 31 is a cross-sectional view schematically illustrating an anti-reflection film of the sixth modified example of Embodiment 2 during a production process.

FIG. 32 is a cross-sectional view schematically illustrating an anti-reflection film of the sixth modified example of Embodiment 2.

FIG. 33 is an example of a schematic cross-sectional view of an anti-reflection film of Comparative Example 1.

FIG. 34 is an example of a schematic cross-sectional view of a conventional anti-reflection film.

### DESCRIPTION OF EMBODIMENTS

The present invention is mentioned in more detail below with reference to embodiments using drawings, but not limited to only these embodiments.

The “moth-eye structure” herein means an uneven structure including protrusions in which the width between the tops of any pair of the adjacent protrusions is equal to or shorter than visible light wavelengths (380 nm or shorter). The “moth-eye surface” herein means a surface of a region in which a moth-eye structure is formed. The “moth-eye sheet” herein means a sheet including a surface with a moth-eye structure, and the “moth-eye film” herein means a film including a surface with a moth-eye structure.

### Embodiment 1

FIG. 1 is a plan view schematically illustrating an anti-reflection film of Embodiment 1. An anti-reflection film 11 of Embodiment 1 includes a first region 13 and a second region (having different characteristics from those of the first region) 15. The first region 13 includes a surface with an uneven structure (a first moth-eye structure) that is composed of a transparent resin in which protrusions are arranged at a cycle (width between the tops of any pair of the adjacent protrusions) smaller than visible light wavelengths. The second region 15 includes a surface with an uneven structure, which is different from the uneven structure in the first region, that is composed of a transparent resin in which protrusions are arranged at a cycle (width between the tops of any pair of the adjacent protrusions) smaller than visible light wavelengths. The first region 13 including a moth-eye structure and the second region 15 including a moth-eye structure are regions where the uneven structure is formed for reducing reflection on the surface of the anti-reflection film 11. The anti-reflection film 11 of Embodiment 1 corresponds to a moth-eye sheet.

In Embodiment 1, as illustrated in FIG. 1, portions having different reflection characteristics from other portions are formed at specific positions or the whole of the anti-reflection film 11 so as to form a pattern. Thus, a visible logo 15L or a visible specific graphic 15F can be formed. A visible symbol can also be formed, which is not illustrated in the figure. In Embodiment 1, the second regions 15 having a shape that forms such a character, symbol, or graphic are not formed by printing on the moth-eye sheet or deforming the moth-eye structure, but are formed by imprinting different uneven structures preliminarily formed on a mold so that different wavelength dispersion characteristics can be provided.

Specifically, a first region is formed on a mold, while a second region having a shape that forms a character, symbol, or graphic, and including a moth-eye pattern (protrusions of an uneven structure) with a height 10% to 20% lower than a moth-eye pattern in the first region is formed on a mold. Then, the character, symbol, or graphic is formed on a film by imprinting the mold.

Thereby, a moth-eye structure is formed also in the portion having a shape that forms a character, symbol, or graphic. Therefore, low reflection characteristics due to the moth-eye pattern in the anti-reflection film are sufficiently favorably obtained without being considerably impaired. Accordingly, the moth-eye structure in the second region with a height 10% to 20% lower than the height of the moth-eye structure in the first region, when used in combination with the moth-eye structure in the first region in a display device, sufficiently improves display performance without impairing display performance. Further, when the display device is not in use such as an undisplayed state, the second region allows the character, symbol, or graphic to be vaguely visible when contrasting with the first region including a moth-eye pattern.

This contributes to, for example, advertisement of products or manufacturers and/or prevention of an accident (collision) due to high transparency of a moth-eye structure, or is preferably used as an accent in a design.

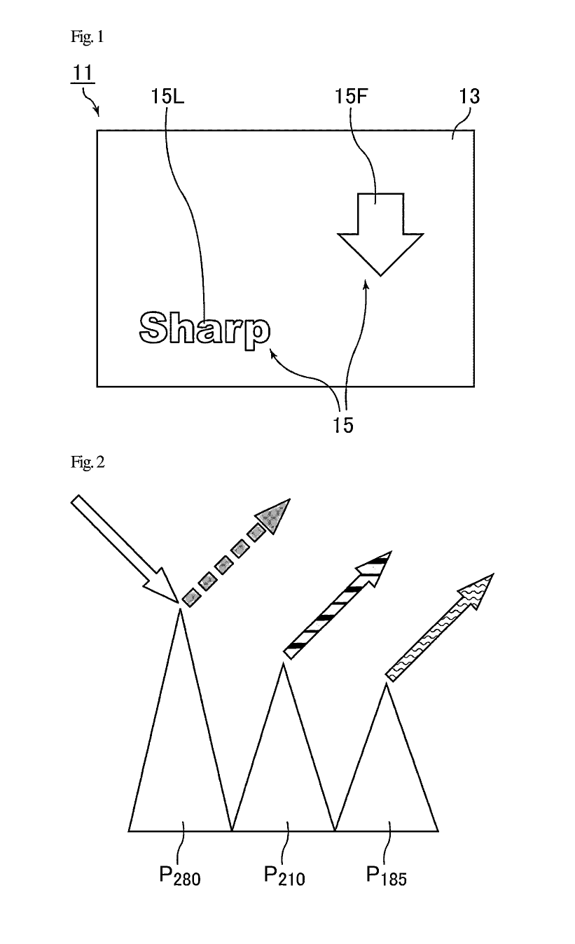

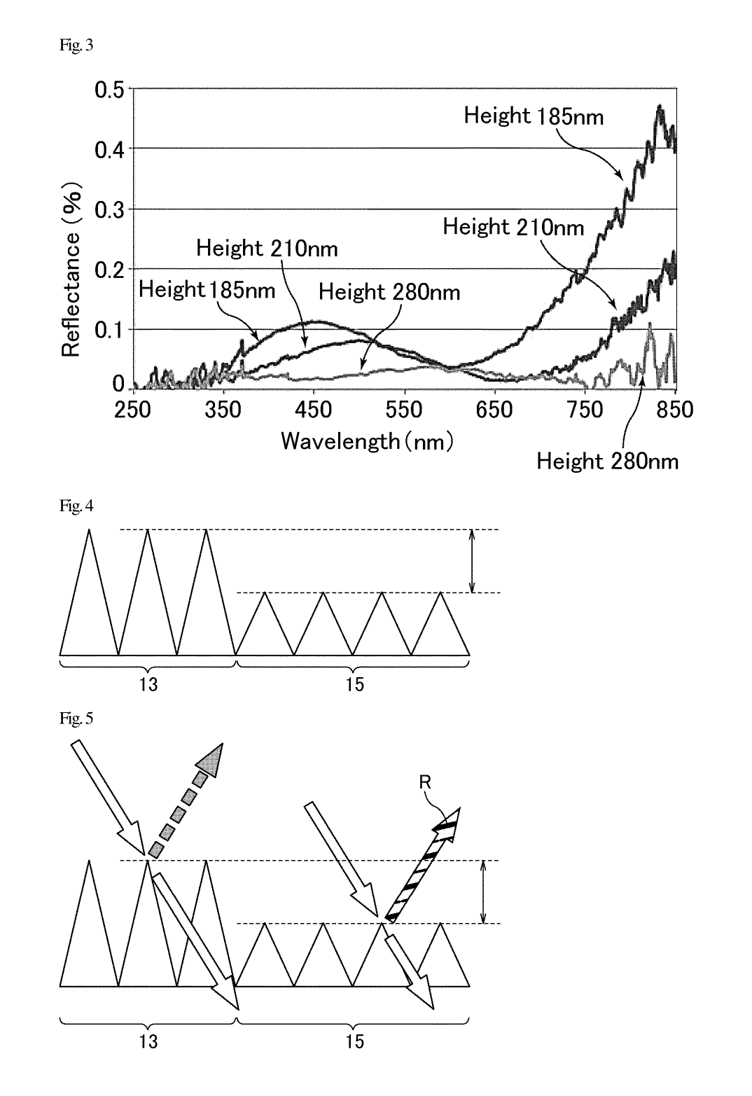

FIG. 2 is a cross-sectional view schematically illustrating protrusions of different heights in a moth-eye structure. FIG. 3 is a graph of reflectance (%) against wavelength (nm) of light on each of the protrusions illustrated in FIG. 2.

Protrusions of the moth-eye pattern are usually arranged with a pitch of not more than 200 nm and have a height of about 200 nm. These are determined so that a region with the moth-eye pattern has sufficiently low and steady (reflectance does not greatly vary due to wavelength) reflection characteristics in a visible light region.

For example, wavelength characteristics (wavelength dependence) of reflectance change with a change in the height of protrusions of the moth-eye pattern. FIGS. 2 and 3 simply illustrate the state of the changes.

In order to obtain sufficiently low reflection characteristics at wavelengths within the range of 380 nm to 780 nm, which is a visible light region, the height of the protrusion of the moth-eye structure is set at higher than 200 nm. At a height of the protrusion around 170 nm, reflectance increases in red-visible wavelength ranges. Therefore, the surface of the moth-eye structure appears reddish a little.

FIG. 3 is a graph of wavelength dependence of the reflectance of the region where moth-eye structures of different heights illustrated in FIG. 2 are formed. Changes are remarkably observed particularly in a long wavelength region with an increase in height of the protrusion of the moth-eye structure.

At the lowest height of the protrusion of 185 nm, reflectance increases in a red range, and the moth-eye surface becomes reddish. At a height of the protrusion of 210 nm, the reflection is suppressed in a red range, and the surface appears greenish. At the highest height of the protrusion of 280 nm, the waveform showing the reflectance is flat in the figure, a peak is not particularly observed against visible light wavelengths, and the reflectance is greatly low in the whole range of visible light wavelengths. Therefore, light reflected on the moth-eye surface is not particularly colored, and is nearly colorless.

This shows that color of light reflected on the moth-eye surface changes depending on the height of the protrusion.

This graph is of specular reflection, in which an incident angle of incident light is set to 5°.

The tinge of reflection varies depending on an angle from which the moth-eye is viewed. The moth-eye structure looks low in height when viewed at an angle from the direction vertical to the moth-eye surface, and reflection increases in a red range. Therefore, when a moth-eye structure with a height of 185 nm is viewed from an angle, reddish is emphasized.

FIGS. 4 and 5 are each a cross-sectional view schematically illustrating a moth-eye structure of an anti-reflection film of Embodiment 1.

In cases where protrusions shorter than those in the first region 13 are partially formed (second region 15) in the moth-eye surface as indicated by double-headed arrows in FIGS. 4 and 5, specifically, protrusions with a height of 185 nm as described above are formed, reflection light R on the moth-eye in the second region 15 can be set to become reddish, for example. On the other hand, in cases where protrusions in a region other than the second region, that is, in the first region 13 having a higher moth-eye structure are set to 280 nm as described above, reflection light is extremely reduced in the region, and the specific color of the reflection light is not emphasized.

When the second region 15 is partially formed as a shape that forms a character, symbol, or graphic as illustrated in FIG. 1, the character, symbol, or graphic is recognized as a region with a different color in the moth-eye surface by contrast with the first region 13.

In Embodiment 1, the second region 15 to be colored also includes the moth-eye structure, and therefore has low reflection characteristics as shown in the graph of FIG. 3. Therefore, the character, symbol, or graphic in the second region 15 is not emphasized too much when viewed through the moth-eye structure.

That is, when the anti-reflection film (moth-eye sheet) 11 is attached to a display surface of a display device, the character, symbol, or graphic does not block the view of displayed images when overlaps the images. Further, when the anti-reflection film 11 is attached to a surface of a display device in an undisplayed state (power off) of the display device, the character, symbol, or graphic appears to be lightly raised on the surface due to reflection. Therefore, a logo or the like, which is displayed, can be used for advertisement. Embodiments other than Embodiment 1 (Embodiment 2 and fourth to sixth modified examples of Embodiment 2) in which a different moth-eye pattern is partially formed can particularly exert the same effects of Embodiment 1.

When the anti-reflection film 11 attached to glass includes protrusions with a height of 280 nm as shown in FIGS. 2 and 3, the glass surface to which the anti-reflection film 11 is attached has extremely low reflectance, and the existence of the glass may not be recognized. Therefore, people may cause a collision accident with the glass surface. However, the anti-reflection film 11 with the second region 15 as a character, symbol, or graphic is well visible, and can therefore be used for calling safety to prevent an accident. For example, the reflectance (Y) of a protrusion with a height of 185 nm (P₁₈₅) is 0.059%. The reflectance (Y) of a protrusion with a height of 210 nm (P₂₁₀) is 0.057%. The reflectance (Y) of a protrusion with a height of 280 nm (P₂₈₀) is 0.031%.

The reflectance (%) refers to a Y value in the XYZ color system (CIE 1931 color system). That is, the reflectance (%) refers to a Y value among X, Y, and Z values of object colors due to reflection, determined by the following equations, in the XYZ color system.

$$X = K {\int }_{380}^{780} S ( λ ) \overline{x} ( λ ) R ( λ ) d λ \\ Y = K {\int }_{380}^{780} S ( λ ) \overline{y} ( λ ) R ( λ ) d λ \\ Z = K {\int }_{380}^{780} S ( λ ) \overline{z} ( λ ) R ( λ ) d λ \\ K = \frac{100}{{\int }_{380}^{780} S ( λ ) \overline{y} ( λ ) d ( λ )} \qquad [ Equation 1 ]$$

S(λ) represents a spectral distribution of a standard light used to display colors,
x̅(λ), y̅(λ), and z̅(λ) each represent color-matching function in the XYZ color system, and
R(λ) represents a spectral reflectance factor.

The Y value, as shown in the above equation, is the integral of the wavelengths within the range of 380 nm to 780 nm of the visible light range, and does not mean reflectance at a specific wavelength.

### Modified Example of Embodiment 1

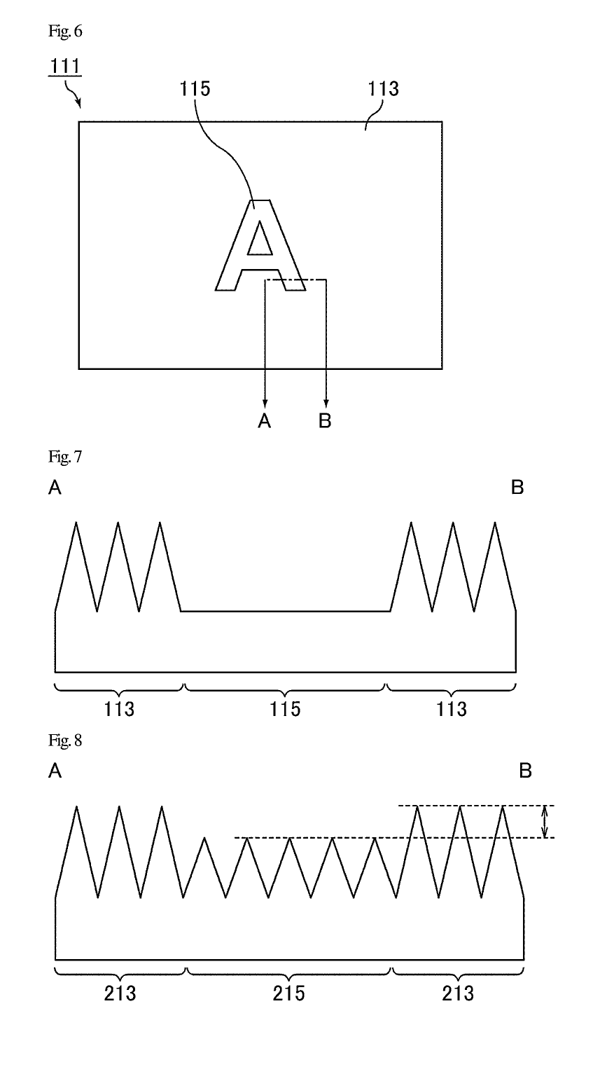

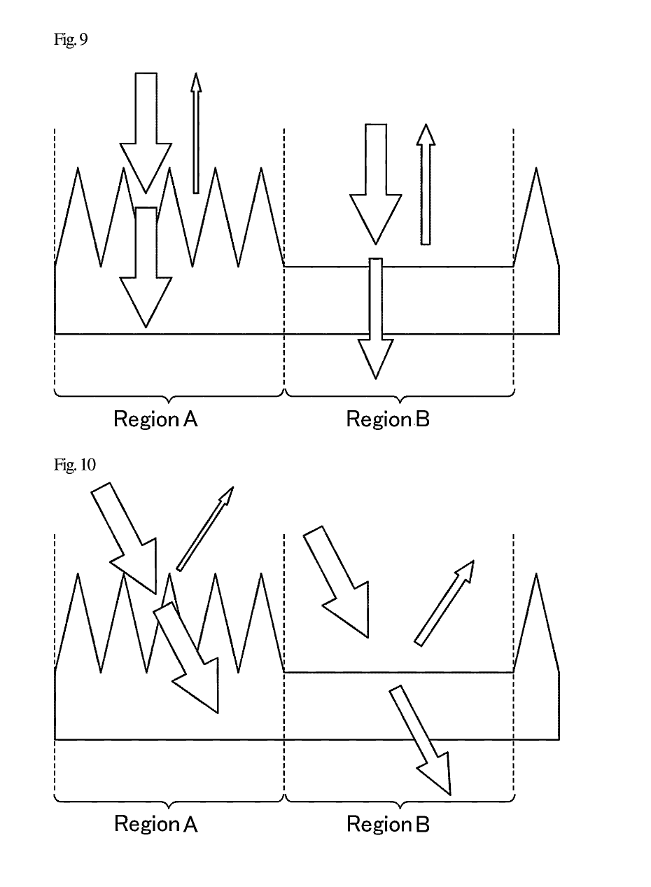

FIG. 6 is a plan view schematically illustrating an anti-reflection film of a modified example of Embodiment 1. FIGS. 7 and 8 are each an example of a cross-sectional view schematically illustrating an anti-reflection film of a modified example of Embodiment 1, and each schematically illustrate a cross section along an A-B line illustrated in FIG. 6.

In cases where a character such as a logo, symbol, or graphic is put on the anti-reflection film (moth-eye sheet) 111 in which a moth-eye structure is formed, a method for preventing the function of the moth-eye structure in such a portion (second region 115) or a method for changing the reflection characteristics of the moth-eye structure in such a portion (second region 115) can be used.

For example, when the character “A” is put on the moth-eye sheet as illustrated in FIG. 6, the character is directly printed using an ink or the like without changing the moth-eye structure that is composed of a transparent resin, which is the simplest method. However, an opaque ink prevents transmission of light, and blocks the view (the case of using an opaque ink is described in Comparative Example 1 described below).

Therefore, in order to prevent the function of the moth-eye structure, a method (1) in which no moth-eye pattern is formed on the portion can be employed. That is, a portion without a moth-eye structure is formed, as illustrated in FIG. 7.

Similar effects can be obtained by performing a method in which the moth-eye structure is filled with a transparent material such as a transparent resin.

In addition, a method (2) in which a moth-eye pattern is partially changed to change the reflection characteristics thereof, as illustrated in FIG. 8. In Embodiment 1, the method (2) is employed.

In both the methods (1) and (2), the first region and the second region are light transmissive. In cases where an anti-reflection film including a moth-eye structure is placed on the front of a display device, the film is attached to a glass plate such as windows or walls. In such a case, a character, symbol, or graphic formed on the anti-reflection film does not significantly impair the light transmittance when viewing through the film.

In the method (1), at a portion (second region 115 in FIG. 7) without moth-eye function, reflection due to a difference of the refractive index at an interface between the portion and a base occurs. For example, when a transparent resin forming the moth-eye surface has a base refractive index of 1.5 and is surrounded by the air, the portion without moth-eye function has a reflectance of 4%, and a difference in reflectance occurs between a portion with a moth-eye structure (reflectance of about 0.1%) and the portion without moth-eye function. In the present embodiment, the base refractive indexes of resin portions without moth-eye function are all 1.5.

The difference in reflectance is easily viewed, and in this case, regions are easily clearly recognized by difference in reflection when viewed from the front.

In the method (2) in which a moth-eye pattern is partially changed to change the reflection characteristics, a character, symbol, or graphic can be displayed by a difference in reflectance characteristics due to the moth-eye pattern. In this case, unlike the method (1), a second region 215 includes a moth-eye pattern, and therefore the difference in reflectance between the second region 215 and a region other than the second region 215 (the difference in reflectance between a first region 213 and the second region 215) is very small. Therefore, when the moth-eye surface is viewed from the front, the second region 215 is difficult to be clearly viewed, on the other hand, when the moth-eye surface is viewed from an angle, the difference in reflectance between the regions tends to increase, and the second region 215 is therefore easily viewed.

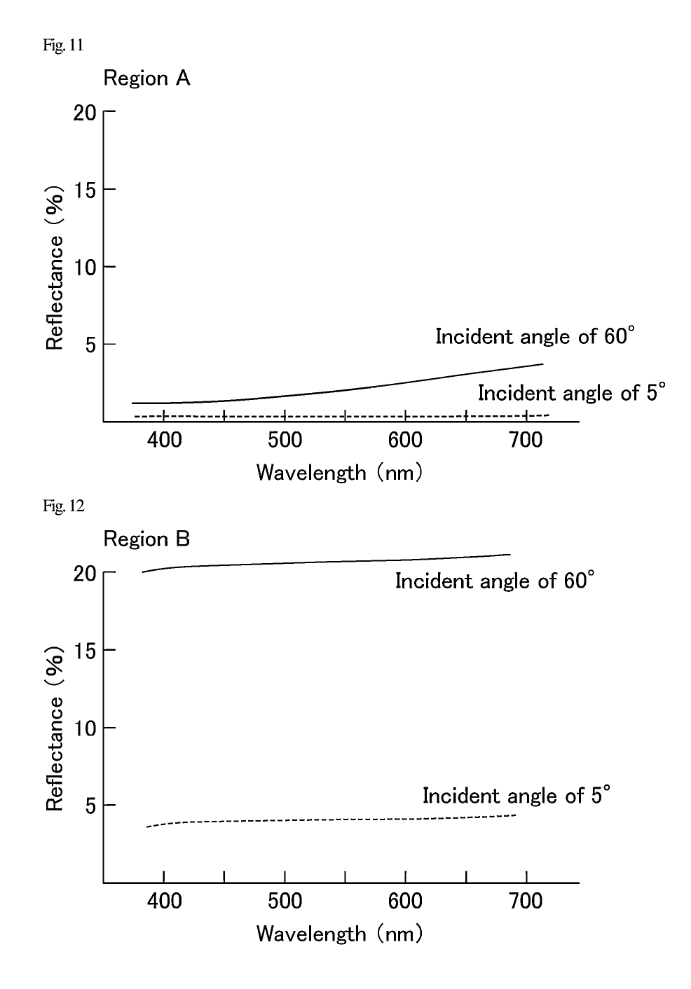

FIG. 9 is a cross-sectional view schematically illustrating the anti-reflection film illustrated in FIG. 7 which is exposed to light entered almost vertically to the film. FIG. 10 is a cross-sectional view schematically illustrating the anti-reflection film illustrated in FIG. 7 which is exposed to light entered at an angle to the film. FIG. 11 is a graph of reflectance (%) against wavelength (nm) of light when light is entered to the region A illustrated in FIG. 9 at an incident angle of 5° from the surface normal and light is entered to the region A illustrated in FIG. 10 at an incident angle of 60° from the surface normal. FIG. 12 is a graph of reflectance (%) against wavelength (nm) of light when light is entered to the region B illustrated in FIG. 9 at an incident angle of 5° from the surface normal and when light is entered to the region B illustrated in FIG. 10 at an incident angle of 60° from the surface normal. In FIGS. 10 and 11, the line of “incident angle of 5°” is obtained when an incident angle from the surface normal is 5°, and the line of “incident angle of 60°” is obtained when an incident angle from the surface normal is 60°.

As in the method (1), when a region without a moth-eye structure or without moth-eye function (hereinafter, referred to as a region B) is partially formed, a difference in reflectance occurs between a region with a moth-eye structure (hereinafter, referred to as a region A) and the region without a moth-eye structure (a region B).

When a transparent resin which is a medium for forming the moth-eye structure has a refractive index of 1.5, and is surrounded by the air, light entered almost vertically to the resin (for example, incident angle (incident angle from the surface normal) is 5°) is reflected at a reflectance of approximately 0.1% on the region A and at a reflectance of 4% on the region B as shown in the graphs in FIGS. 11 and 12, and the difference between the reflectances allows recognition of a difference in reflection between the regions A and B even when viewed from the front.

Further, when viewed from an angle, a difference in reflection can be recognized because of a large difference between the reflectances (see FIGS. 11 and 12).

The region B having a high reflectance, however, does not block the view (is a translucent region). Therefore, the region B does not block the view of a display screen of a display device even when a film with such a region B is placed on the front of the display device.

The region B is visible from any direction, and the reflectance is generally significantly reduced by means of an anti-reflection film including a moth-eye pattern. Therefore, the occurrence of an accident such as collision with walls, which may not be visually recognized, may be concerned. However, a moth-eye surface partially including such a region B allows visual recognition of walls, and is therefore particularly useful for prevention of an accident.

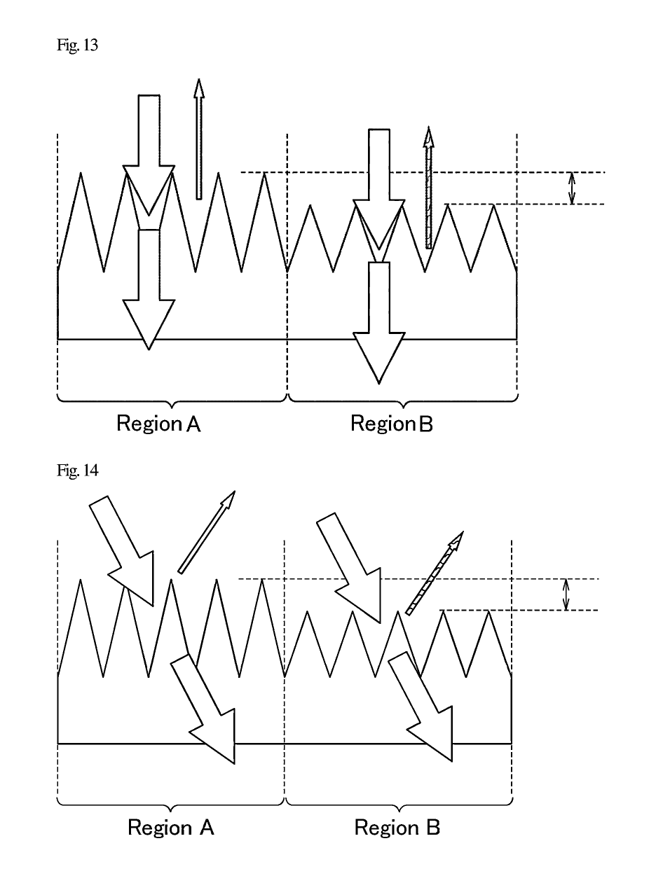

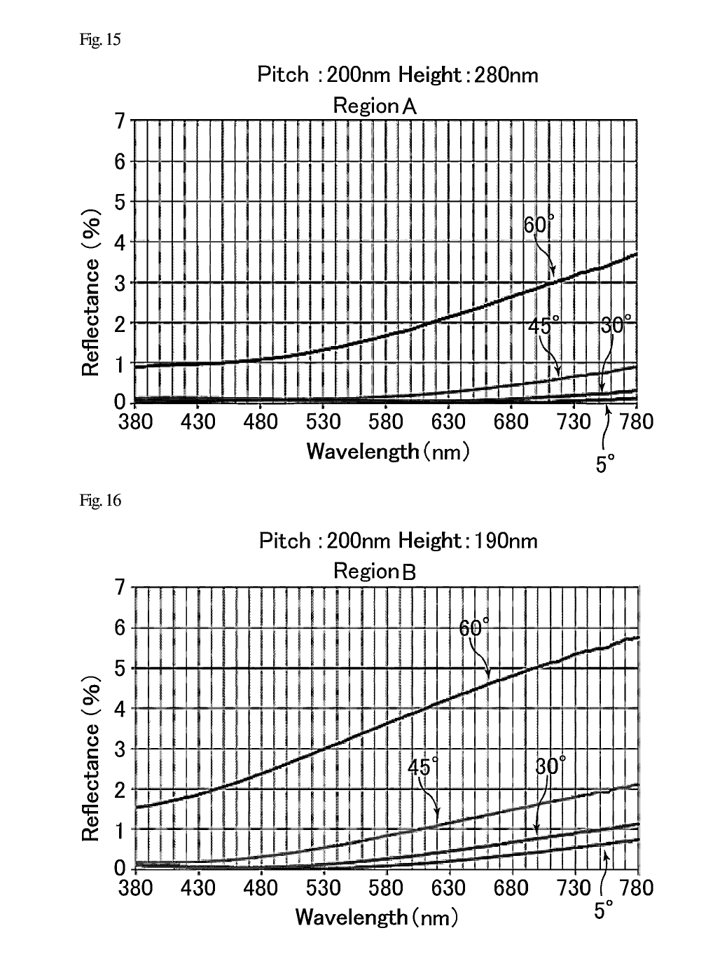

FIG. 13 is a cross-sectional view schematically illustrating the anti-reflection film illustrated in FIG. 8 which is exposed to light entered almost vertically to the film. FIG. 14 is a cross-sectional view schematically illustrating the anti-reflection film illustrated in FIG. 8 which is exposed to light entered at an angle to the film. FIG. 15 is a graph of reflectance (%) against wavelength (nm) of light when light is entered at different incident angles to the region A illustrated in FIGS. 13 and 14. FIG. 16 is a graph of reflectance (%) against wavelength (nm) of light when light is entered at different incident angles to the region B illustrated in FIGS. 13 and 14.

The graphs in FIGS. 15 and 16 are each obtained by measuring the reflectance of a moth-eye surface including a moth-eye structure. The height of the moth-eye structure is different between FIGS. 15 and 16. In the measurement of the reflectance in both the graphs, an incident angle of light is varied relative to the normal to the moth-eye surface.

The reflectance of the moth-eye surface becomes the lowest when the incident angle of light is close to the right angle to the surface. The graphs show that an increase rate of the reflectance becomes higher as the incident angle (angle between the normal to the moth-eye surface and the incident direction) becomes larger, toward a longer wavelength side. Further, an increase rate of the reflectance relative to an incident angle is gentle in a higher moth-eye structure (moth-eye structure in the region A with a height of 280 nm).

In cases where the region A including a higher moth-eye structure (the height of the protrusion is 280 nm) and the region B including a lower moth-eye structure (the height of the protrusion is 190 nm) are formed adjacent to each other as illustrated in FIGS. 13 and 14, both the regions A and B show very low reflectances of light entered almost vertically to the regions, as can be noted in the graphs in FIGS. 15 and 16, and a difference between the reflectances is very small. Therefore, the boundary between the regions is hardly recognized or the region including slightly lower protrusions (the region B) is recognized as a region generating reddish reflection light.

When the incident angle increases to, for example, 60°, the difference between the reflectance of the region A and the reflectance of the region B is approximately 2%, and the difference between the regions is therefore recognized, and the boundary between the regions is also recognized.

Therefore, in the method (2), for example, when a portion having a shape that forms a character, symbol, or graphic is formed to have the pattern of the region B (region including lower protrusions), the difference between the regions is not clearly recognized when viewed from the front, but when viewed from an angle, the portion including the pattern of the region B is distinctly visible because of the difference in the reflection characteristics of the regions. Accordingly, the character, symbol, or graphic is recognized.

In such a method of changing the height of the moth-eye structure, the regions A and B can preferably be separately formed more simply and surely without changing anodization conditions and etching conditions between the regions.

Protrusions and depressions of the moth-eye structure of the anti-reflection film of Embodiment 1 may include a structure in which a plurality of fine protrusions are aligned in a repeating unit at a cycle smaller than visible light wavelengths. In the moth-eye structure, a tip of the protrusion is a top, and a point at which the adjacent protrusions are in contact with each other is a bottom. The width between the tops of any pair of the adjacent protrusions of the moth-eye structure is defined as a distance between two points where perpendicular lines from the respective tops come in contact with a same plane surface (when the moss-eye surface is viewed in plan). Further, the height from the top to the bottom of the moth-eye structure is represented by the distance between the top of a protrusion and a point where a perpendicular line from the top comes in contact with a plane surface in which the bottom of the protrusion exists.

In the anti-reflection film of Embodiment 1, the width between the tops of any pair of the adjacent protrusions of the moth-eye structure is 380 nm or shorter, preferably 300 nm or shorter, and more preferably 200 nm or shorter. The width may be controlled within the value ranges substantially entirely in the moth-eye structure, and may be not partially controlled within the value ranges in the moth-eye structure. The figures show the unit structure of the moth-eye structure with a conical shape, but the unit structure may have, for example, a square pyramid shape. The shape of the unit structure is not particularly limited as long as a top and a bottom are formed and the width between the tops of any pair of the adjacent protrusions of the uneven structure is controlled within the above value ranges.

The following description will discuss a principle of the ability of the anti-reflection film including the moth-eye structure of Embodiment 1 to achieve low reflection. The moth-eye structure in the anti-reflection film of Embodiment 1 includes protrusions and a foundation portion. When light passes from one medium to a different medium, the light is refracted on an interface between the media. The refraction angle depends on the refractive index of the medium into which the light proceeds. For example, when the medium is air or a resin, the refractive index is approximately 1.0 or approximately 1.5, respectively. In Embodiment 1, the unit structure of the uneven structure formed on the surface of the anti-reflection film includes a cone shape, i.e., a shape in which the width gradually decreases toward the tip end. On the protrusion located at an interface between an air layer and the anti-reflection film, the refractive index is considered to continuously and gradually increase from approximately 1.0 as the refractive index of air to the refractive index of the material forming the film (approximately 1.5 in case of resin). The amount of light reflection is proportional to the difference between the refractive indexes of these media, and thus most light passes through the anti-reflection film by creating a condition of substantial absence of the refractive interface as described earlier. As a result, the reflectance on the surface of the film is reduced significantly.

The display device of Embodiment 1 is a liquid crystal display device (LCD), and includes the anti-reflection film of Embodiment 1 on the display surface. On the display surface, the reflection can be sufficiently reduced and the transmittance can be sufficiently improved by means of the moth-eye structure, while regions of different reflection characteristics are mixed.

A panel portion of the LCD of Embodiment 1 includes a pair of substrates and a liquid crystal layer interposed between the pair of substrates. The pair of substrates may take a configuration consisting of an array substrate on one side and a color filter substrate on the other side, and electrodes may be placed in at least one of the pair of the substrates. The liquid crystal layer can be driven and controlled by the influence of the electric field generated between these electrodes. In Embodiment 1, other configurations may be employed without any limitation, such as a configuration in which one of the substrates functions as both an array substrate and a color filter substrate. Moreover, the method of controlling alignment of liquid crystal molecules in the liquid crystal layer is not particularly limited, and may be a TN (Twisted Nematic) mode, a VA (Vertical Alignment) mode, or an IPS (In-Plane Switching) mode. A light control element such as a polarizing plate is placed on the opposite side of the liquid crystal layer side of the array substrate and the color filter substrate.

The array substrate includes a supporting substrate made of glass, plastic, or the like, on which are mounted a wiring, an electrode, and the like for controlling the alignment of liquid crystal molecules in the liquid crystal layer. The method of driving liquid crystal may be passive matrix type or active matrix type. In the matrix type driving method, wirings are arranged to intersect each other. A plurality of regions surrounded by the wirings form a matrix configuration. The wirings and the electrodes preferably include a material such as aluminum (Al), silver (Ag), tantalum nitride (TaN), titanium nitride (TiN), and molybdenum nitride (MoN) for excellent functionality and productivity.

In the case of the active matrix type, a semiconductor switching element such as a thin film transistor (TFT) which controls signals transmitted from each of the wirings is placed at each intersection of the wirings. The TFT includes an electrode for applying a bias voltage to a semiconductor layer. The aforementioned materials for the wirings and the electrodes are also preferably used as the materials for the electrode, and thus the electrode has reflecting properties.

An interlayer insulation film is formed on the wirings and the TFT. Further, on the interlayer insulation film, a pixel electrode formed of a translucent material is placed in a manner to overlap the region surrounded by the wirings. The pixel electrode is composed of a translucent metal oxide, such as ITO (Indium Tin Oxide) and IZO (Indium Zinc Oxide).

The color filter substrate includes a supporting substrate made of glass, plastic, or the like, and on which are mounted a resin layer such as a color filter layer, a black matrix layer, and the like. In addition, a counter electrode formed of a translucent material is provided over the resin layer. The counter electrode is also composed of a metal oxide such as ITO and IZO, like the pixel electrode. In Embodiment 1, the anti-reflection film of Embodiment 1 is mounted on the display surface (observation surface) side of the color filter substrate.

The display device of Embodiment 1 is not limited to such an LCD, and may be a display device such as a PDP and an EL.

In Embodiment 1, the configurations and the effects of the anti-reflection film of the present invention are mainly explained. In Embodiment 2, the preferred method for producing the anti-reflection film of the present invention is mainly explained, and embodiments of the anti-reflection film of the present invention are explained in more detail below. In Embodiment 2, the embodiment described in Embodiment 1 is also explained.

### Embodiment 2

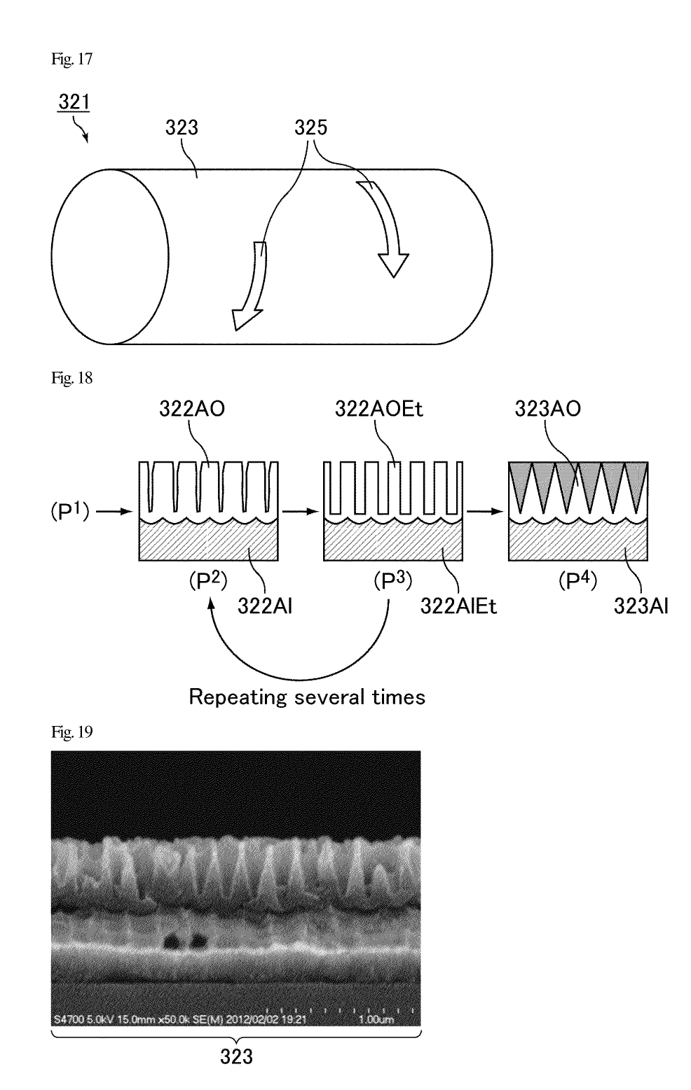

FIG. 17 is a schematic view of an imprint mold of Embodiment 2. A method for preparing a moth-eye surface in which the reflection characteristics are partially changed is described in detail below.

A moth-eye structure is formed by continuous transcription of a female pattern which is formed on the surface of an imprint mold 321 with a shape such as a roll shape. An example of a method for preparing an anti-reflection film using the roll-shaped imprint mold 321 is herein described.

The roll-shaped imprint mold 321 is, for example, a roll-shaped mold made by cutting aluminum (Al) or a thin sleeve tube as a base with an aluminum film on the surface in which the aluminum surface is repeatedly anodized and etched. That is, alumina (Al₂O₃) with a plurality of fine holes (pores) having a size of a visible light wavelength or less formed by anodization of aluminum (hereinafter, also referred to as anodized porous alumina) is formed on a large area of the surface of the imprint mold. The final shape of each protrusion formed on the anodized porous alumina is a triangle in the cross section, and the shape is formed by repeating step by step the pore formation by anodization of aluminum and etching of the anodic oxide film.

Specifically, anodization, etching, anodization, etching, anodization, etching, anodization, etching and anodization (anodization: 5 times, etching: 4 times) are performed in the stated order to prepare the mold. Repeating of the anodization and the etching provides fine holes with a shape tapered toward the inside of the mold.

The imprint mold is not limited to a roll-shaped mold made by cutting aluminum or a thin sleeve tube on which an aluminum film is formed, and may be made of glass or a metallic material such as SUS or Ni, or a resin material such as polypropylene, polymethylpentene, polyolefin-based resin formed from a cyclic olefin-based polymer (represented by typical norbornene-based resins such as a product named “Zeonor” (manufactured by Zeon Corporation) and a product named “Arton” (manufactured by JSR Corporation)), polycarbonate resin, polyethylene terephthalate, polyethylene naphthalate, or triacetyl cellulose. The imprint mold may be a flat plate-shape.

In Embodiment 2, as illustrated in FIG. 17, a desired pattern 325 is preliminarily printed by stamping or the like using a resin such as a resist before anodization. Then, the surface is treated by anodization and etching.

For example, after first anodization and first etching, the formed pattern 325 is dissolved with a solvent. Then, anodization and etching are performed again.

Through these processes, a portion in which the pattern 325 was present is treated by a smaller number of treatment processes as compared to other portions. Accordingly, after performing each of anodization and etching multiple times, the portion in which the pattern 325 was present includes a shallower concave (the second region in the imprint mold 321) than a portion therearound.

Such a shallower concave in the thus prepared mold forms a moth-eye pattern with a smaller height in a moth-eye surface (the second region of the anti-reflection film is formed). The reflection characteristics of the second region are different from those of the first region which is around the second region.

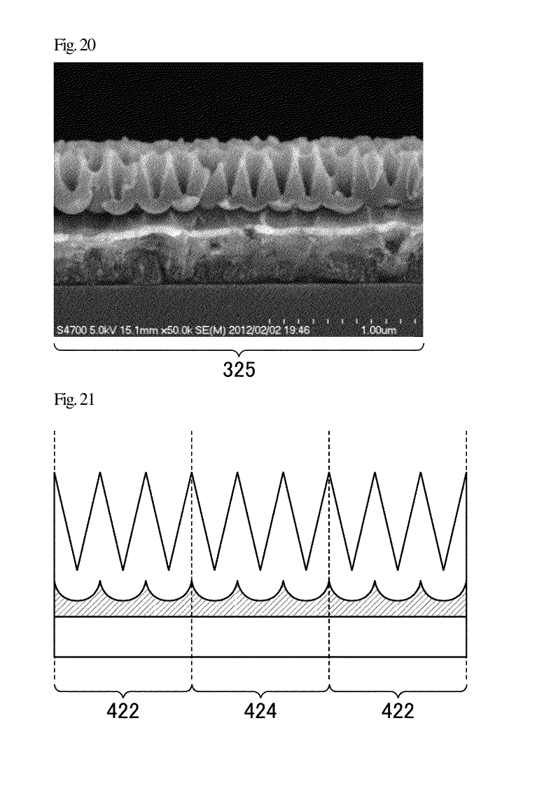

Next, the following description will specifically discuss a method for preparing an imprint mold referring to a cross-sectional view. The imprint mold with a moth-eye pattern is produced as follows. FIG. 18 is a cross-sectional view schematically showing a production process flow of an imprint mold of Embodiment 2. Processes (P¹) to (P⁴) indicate production processes. FIGS. 19 and 20 are each a photograph of the cross section of an imprint mold of Embodiment 2.

### <Preparation of Imprint Mold>

First, as described above, an aluminum film is formed on a base such as a thin sleeve tube (process P¹). The thickness of the film may be set at, for example, 1.0 μm. Next, anodization is performed (process P²) in a liquid under the following conditions: oxalic acid; 0.6 wt %, liquid temperature; 5° C., and applied voltage; 80V. Holes different in size (depth) are formed by controlling the anodization time. The anodization time is, for example, 30 seconds. In the anodizing process (process P²), an aluminum film turns into an aluminum oxide 322AO, and holes are formed with approximately constant intervals depending on an applied voltage.

Next, after anodization, the base is subjected to etching (process P³) in a phosphoric acid solution. The etching is performed, for example, using a 1 mol/l phosphoric acid solution at a liquid temperature of 30° C. for 30 minutes. In the etching process P³, the holes previously formed are isotropically etched to become large (widening).

Subsequently, an anodization process P² is performed again under the same conditions as the initial anodization. In this process, the holes previously widened by the etching process are deepened in the film thickness direction by anodization. Then, widening is performed by an etching process P³. In this process, the holes deeply formed by the second anodization process P² and the holes widened by the first anodization process P² and the first etching process P³ are both etched to be further widened.

Pores are formed in a desired substantially conical shape by performing anodization process and etching process several times, as illustrated by a process P⁴ in FIG. 18. That is, holes with an inverted cone shape are formed on the surface of the imprint mold as shown in photographs in FIGS. 19 and 20. The shape of the holes is controlled by an anodization time and an etching time. For example, FIG. 19 is a photograph of an example of deeply formed holes, and FIG. 20 is a photograph of an example of shallowly formed holes. The shape of the holes is also controlled by the number of times of anodization processes and etching processes. In order to partially change the height of the moth-eye structure, a portion with a small depth (second region) may be, for example, formed on the imprint mold. Specifically, a pattern is printed with a resist or the like on a mold, and the mold is subjected to each of anodization and etching once, the resist is peeled, and then the mold is entirely anodized and etched. Thus, the region having been covered with the resist can preferably be shallowly formed.

### <Imprint Process>

Next, a moth-eye structure is formed using the imprint mold prepared in the aforementioned processes. In this process, for example, a translucent photopolymerizable resin solution is dropped on the surface of the imprint mold, a base is attached to the imprint mold, and the resin layer is irradiated with ultra violet (UV) light to be cured to form a resin film. A laminate film of the cured resin film and the base film is peeled from the mold. Here, the photopolymerizable resin solution is applied to the base (for example, TAC film), which is transferred by a conveyer system, for example, by a coating method using a gravure roll or a die coating method, and the resin is dried at 80° C. The resin is pressed to a rotating roll-shaped imprint mold, exposed to light to a cumulative light dose of 2 J/cm², and peeled from the imprint mold. These processes are sequentially and continuously performed as a common roll-to-roll system, thereby imprinting the protrusions and depressions of the imprint mold on the film. Thus, a film including a moth-eye structure is prepared.

The imprint process may be performed by any method other than the above method, and examples of the method include a duplicating method such as a heat pressing method (embossing method), an injection molding method, and a sol-gel method; a method of laminating a shaped sheet with fine protrusions and depressions; and a method of imprinting a layer with fine protrusions and depressions. The imprint process may be appropriately selected therefrom to suit the use of an anti-reflection product and a material of the base.

### Modified Example of Embodiment 2

The following description will discuss a method for producing an anti-reflection film of a modified example of Embodiment 2. In the production method below, an imprint mold is first produced for forming protrusions and depressions on an anti-reflection film of a modified example of Embodiment 2. The imprint mold is pressed to the surface of a resin film applied to the surface of a base so as to transfer (imprint) the uneven pattern formed on the imprint mold to the film surface. Simultaneously, the resin film is cured under a certain condition to cure the uneven pattern imprinted to the surface of the anti-reflection film so that a predetermined uneven pattern is molded. The following description will also discuss a method for preparing an imprint mold for preparing the anti-reflection film as the method for preparing the anti-reflection film.

First, a method for preparing the anti-reflection film is systematically explained with the lists of various embodiments of the present invention.

(1) A portion without a moth-eye pattern (uneven structure) is partially formed.

Thereby, the portion without a moth-eye pattern (second region) is particularly easily viewed. Even when viewed from the front, the portion can be recognized due to a difference in reflection (modified example of Embodiment 1, first to third modified examples of Embodiment 2 described below). This embodiment is preferred for risk prevention.

### (1)-i: A Method on a Mold

(1)-i-A: An uneven structure of the mold is filled.
(1)-i-B: A portion without a moth-eye structure is partially formed on the mold during processes.
(1)-i-B-a: The mold is partially masked, and the masked portion is prevented from being subjected to anodization/etching (AO/Et).

### (1)-ii: A Method on a Film

Specifically, a portion (second region) of the film is filled.

(2) A moth-eye pattern is partially changed. This method has an advantage that the portion with a changed pattern is hardly viewed from the front, and is therefore not distracting. The portion can be clearly viewed from an angle (Embodiments 1 and 2, fourth to sixth modified examples of Embodiment 2 described below). This embodiment is preferred for displaying, for example, a logo or advertisement.

### (2)-i: A Method on a Mold

Specifically, protrusions are partially reduced in height.

(2)-i-A: A pattern is changed by eliminating part of AO/Et.
(2)-i-A-a: The mold is partially masked, and AO/Et is performed. The mask is removed between the AO/Et.
(2)-i-B: The mold is partially filled.
(2)-i-B-a: The mold is partially filled by printing such as inkjet printing in which the amount of ink to be ejected can be changed and controlled to the minimum.
(2)-i-C: Resistance of the mold is partially changed so that the pattern is changed.
(2)-i-C-a: A film thickness is changed.
(2)-i-C-b: A material is changed.
(2)-i-D: Conditions for preparing the mold is partially changed.
(2)-i-D-a: An electrode used in AO is shaped to fit the shape that forms a character, symbol, or graphic, and the distance between the electrodes is reduced.

### (2)-ii: A Method on Film

Specifically, a portion (second region) of the film is partially filled by printing such as inkjet printing in which the amount of ink to be ejected can be changed and controlled to the minimum.

Among these, the methods (1)-i-A, (1)-i-B, and (2)-i-A-a are easily performed.

### First Modified Example of Embodiment 2

### Example of (1)-i-A

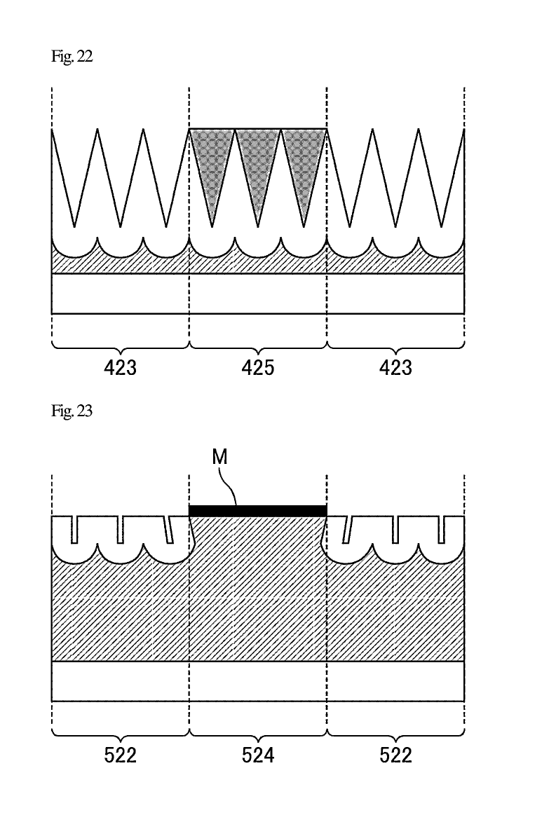

FIG. 21 is a cross-sectional view schematically illustrating an imprint mold of the first modified example of Embodiment 2 during a production process. FIG. 22 is a cross-sectional view schematically illustrating an imprint mold of the first modified example of Embodiment 2.

A moth-eye pattern in a mold is formed, and then is partially filled. Thereby, a region capable of imprinting a moth-eye pattern (first region 423) and a region capable of not imprinting a moth-eye pattern (second region 425) are formed. The moth-eye structure in the imprint mold herein is also referred to as a moth-eye pattern in a mold.

### Second Modified Example of Embodiment 2

### Example of (1)-i-B

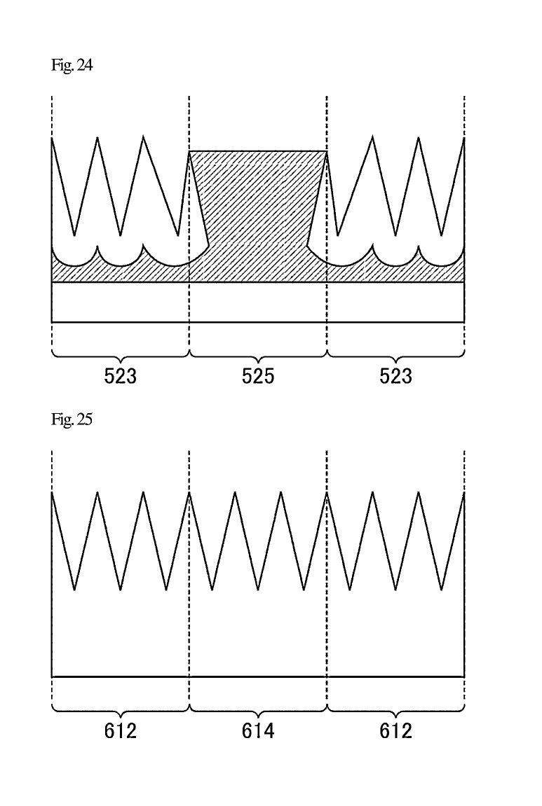

FIG. 23 is a cross-sectional view schematically illustrating an imprint mold of the second modified example of Embodiment 2 during a production process. FIG. 24 is a cross-sectional view schematically illustrating an imprint mold of the second modified example of Embodiment 2.

During production process of an imprint mold, the mold is partially covered with a mask M (second region 524 during the production process), and the masked portion is free from the formation of an uneven structure (second region 525).

### Third Modified Example of Embodiment 2

### Example of (1)-ii

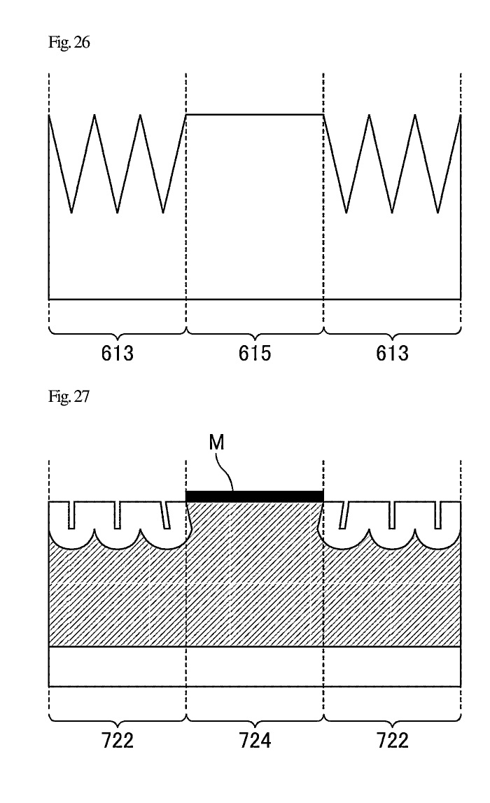

FIG. 25 is a cross-sectional view schematically illustrating an anti-reflection film of the third modified example of Embodiment 2 during a production process. FIG. 26 is a cross-sectional view schematically illustrating an anti-reflection film of the third modified example of Embodiment 2.

The moth-eye structure on the anti-reflection film (film) is partially filled with a transparent resin (second region 615) to form a portion without moth-eye function.

### Fourth Modified Example of Embodiment 2

### Example of (2)-i-A

FIG. 27 is a cross-sectional view schematically illustrating an imprint mold of the fourth modified example of Embodiment 2 during a production process. FIG. 28 is a cross-sectional view schematically illustrating an imprint mold of the fourth modified example of Embodiment 2.

Anodization (AO) processes/etching (Et) processes as processes for preparing a moth-eye pattern in a mold are partially skipped by performing masking. Since not all of the processes are skipped, the height of protrusions in a region having been masked (second region 725) is lower than those in a first region 723 therearound.

### Fifth Modified Example of Embodiment 2

### Example of (2)-i-B

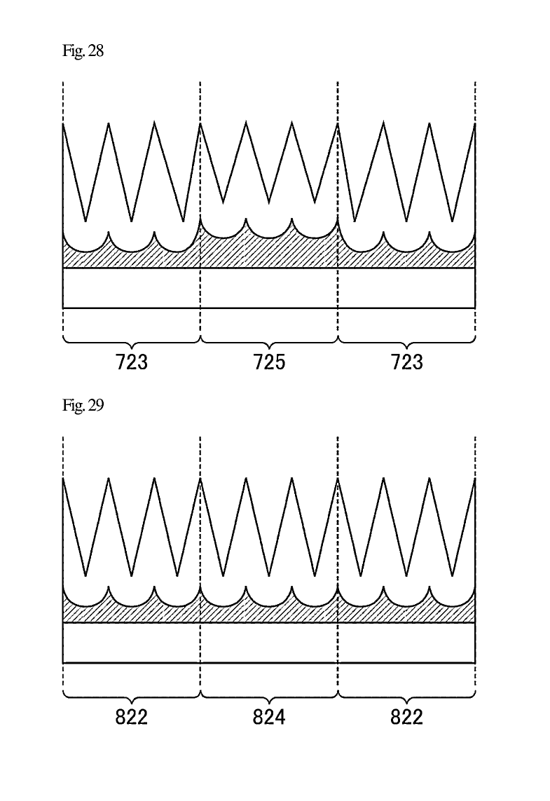

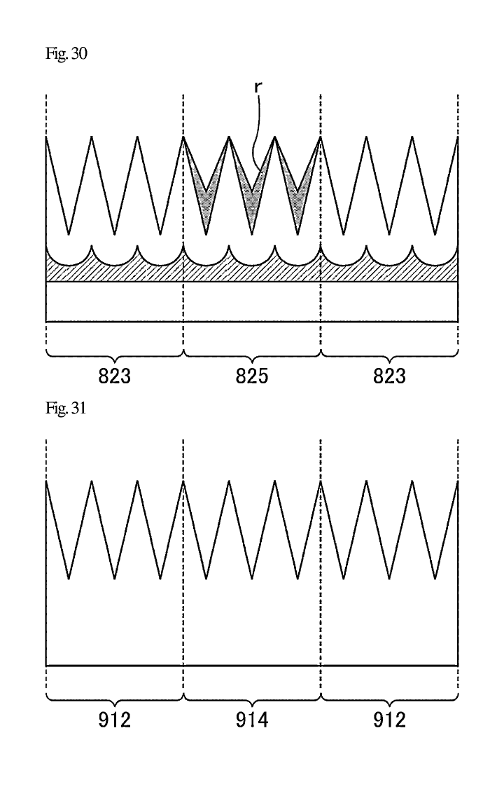

FIG. 29 is a cross-sectional view schematically illustrating an imprint mold of the fifth modified example of Embodiment 2 during a production process. FIG. 30 is a cross-sectional view schematically illustrating an imprint mold of the fifth modified example of Embodiment 2.

A moth-eye pattern in a mold is formed as illustrated in FIG. 29 as usual, and then a resin r is applied to a specific region (second region 825) (holes are not completely filled).

### Sixth Modified Example of Embodiment 2

### Example of (2)-ii

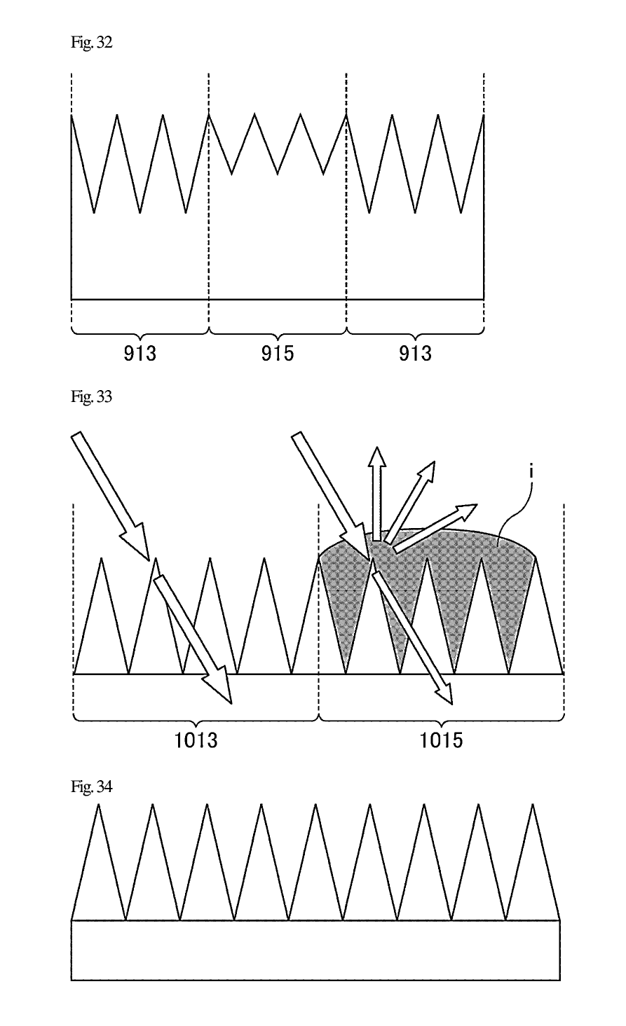

FIG. 31 is a cross-sectional view schematically illustrating an anti-reflection film of the sixth modified example of Embodiment 2 during a production process. FIG. 32 is a cross-sectional view schematically illustrating an anti-reflection film of the sixth modified example of Embodiment 2.

A transparent resin is partially applied to a film including a imprinted moth-eye pattern in a mold (second region 915 in FIG. 32) (moth-eye pattern is not completely filled).

The embodiments of the imprint mold described above are also embodiments of the anti-reflection structure and the display device because the anti-reflection structure of the present invention and the display device of the present invention including the anti-reflection structure can be prepared using the imprint mold. Further, the embodiments of the anti-reflection structure are also embodiments of the display device because the display device of the present invention including the anti-reflection structure can be prepared.

The configurations of the uneven structure and the like of the present invention are confirmed by electron microscope (SEM) observation.

The moth-eye structure provided in the anti-reflection film of Embodiment 2 is the same as the moth-eye structure provided in the anti-reflection film of Embodiment 1, and the width between the tops of any pair of the adjacent protrusions is designed to be equal to or less than visible light wavelengths. The configuration of Embodiment 1 described above can be appropriately applicable to other configurations of Embodiment 2.

### Other Embodiments

In the above embodiments, the surfaces of the imprint mold, the anti-reflection film, and the display device are almost flat except for portions including protrusions and depressions of the moth-eye structure. A scattering uneven structure may be formed by performing sandblasting prior to anodization.

The anti-reflection film in each embodiment includes as a main component a resin such as a photocurable resin or a thermosetting resin which are curable under certain conditions because the moth-eye structure can be precisely formed therein. In (inner portion of) the foundation layer or the like of the anti-reflection film, a material (transparent beads or the like) having a different refractive index from a resin material as a main component of the anti-reflection film may be partially dispersed.

In the anodization process described in Embodiment 2, an oxalic acid is used, and further an acidic electrolyte solution such as sulfuric acid or phosphoric acid, or an alkaline electrolyte solution may be used.

The above description has discussed the method of producing the imprint mold for forming the moth-eye structure in the anti-reflection film. The method for producing the imprint mold is not limited thereto. Examples of the method, in addition to the aforementioned anodization and the etching, include electron beam lithography and laser interference exposure.

Embodiment 1 shows one example of the anti-reflection film as the anti-reflection structure of the present invention. The anti-reflection structure of the present invention is not limited to the anti-reflection film, and may be used for, for example, every objects to be seen and every tools used to see, such as building materials (e.g. window glass), tanks, and hydroscopes.

The anti-reflection structure of the present invention includes a moth-eye structure that is composed of a transparent body. A base placed under the moth-eye structure may be composed of an opaque body or a low light transmissive material instead of a transparent body. The base may be, for example, a colored glass substrate, a black colored acrylic substrate, or a film for photographs. In cases where the moth-eye structure formed on a transparent base made of glass, acrylic, or the like has a refractive index similar to the refractive index of the transparent base, the structure remarkably suppresses surface reflection on the transparent base and enhances the transmission visibility. However, the reduction effect of the surface reflection imparted by the moth-eye structure can be obtained even when the base is not composed of a transparent body.

The following description will also discuss the case of a black colored acrylic substrate. For example, 4% of light, which is the same percentage of the reflectance of the transparent body, is reflected on the surface of the acrylic substrate including the surface without moth-eye structure, and the rest of light goes directly to the acrylic substrate and is absorbed into the substrate. In this case, even though the rest of light is adsorbed into the substrate, apparent surface reflection is clearly recognized on the surface of the substrate, and a shiny surface with gloss black, called piano black, is observed. On the other hand, a substrate including a moth-eye structure on the surface has a surface reflectance reduced to approximately 0.1% or less, and approximately 99.9% of light is absorbed into the substrate. In this case, the surface appears glossy black, but is more suppressed from reflecting (light is less reflected), and thereby deep color appearance is obtained. Such a surface may be used for decorative purposes. A method of providing the moth-eye structure on the surface of the acrylic substrate may be as follows: the moth-eye structure made of a transparent material may be directly attached to the acrylic substrate or the moth-eye structure made of a transparent material is attached on a transparent base, and the base is attached to the acrylic substrate.

Further, the formation of the moth-eye structure on a surface of a photograph suppresses surface reflection to improve apparent contrast, and thereby deep color appearance is obtained.

### Comparative Example 1

FIG. 33 is an example of a schematic cross-sectional view of an anti-reflection film of Comparative Example 1. A symbol is directly printed with an ink i without changing the moth-eye structure that is composed of a transparent resin. Light cannot pass through the opaque ink i, and the view is blocked.

The embodiments can be suitably combined with each other without departing from the scope of the present invention.

### REFERENCE SIGNS LIST

11, 111: Anti-reflection film
13, 113, 213, 613, 913: First region (of anti-reflection film)
15, 115, 215, 615, 915: Second region (of anti-reflection film)
15L: Logo
15F: Graphic
321: Imprint mold
322AO, 322AOEt, 323AO: Aluminum oxide
322Al, 322AlEt, 323Al: Aluminum
323, 423, 523, 723, 823: First region (of imprint mold)
325, 425, 525, 725, 825: Second region (of imprint mold)
422, 522, 722, 822: First region (of imprint mold during a production process)
424, 524, 724, 824: Second region (of imprint mold during a production process)
612, 912: First region (of anti-reflection film during a production process)
614, 914: Second region (of anti-reflection film during a production process)
1013, 1015: Region
i: Ink
M: Mask
r: Resin

1. An anti-reflection structure comprising:
a surface with an uneven structure that is composed of a transparent body and includes protrusions, the width between the tops of any pair of the adjacent protrusions being equal to or shorter than visible light wavelengths,
the anti-reflection structure comprising a first region including a surface with the uneven structure, and a second region including a surface with a structure that is composed of a transparent body, the structure being different from the uneven structure in the first region,
the second region in a plan view having a shape that forms at least one selected from the group consisting of characters, symbols, and graphics.

2. The anti-reflection structure according to claim 1,
wherein the second region is intended to be used to enhance visibility for calling attention.

3. The anti-reflection structure according to claim 1,
wherein the second region is used as a logo and/or an advertisement.

4. The anti-reflection structure according to claim 1,
wherein the anti-reflection structure is an anti-reflection film that is composed of a transparent resin.

5. The anti-reflection structure according to claim 4,
wherein the structure in the second region is an uneven structure including protrusions, the width between the tops of any pair of the adjacent protrusions being equal to or shorter than visible light wavelengths.

6. The anti-reflection structure according to claim 5,
wherein a protrusion of the uneven structure in the second region is different in height from a protrusion of the uneven structure in the first region.

7. The anti-reflection structure according to claim 5,
wherein the uneven structure in the second region is different in shape from the uneven structure in the first region.

8. The anti-reflection structure according to claim 1,
wherein the structure in the second region is not an uneven structure including protrusions, the width between the tops of any pair of the adjacent protrusions being equal to or shorter than visible light wavelengths.

9-11. (canceled)

12. An imprint mold comprising:
a surface with an uneven structure including protrusions, the width between the tops of any pair of the adjacent protrusions being equal to or shorter than visible light wavelengths,
the imprint mold comprising a first region including a surface with the uneven structure and a second region including a surface with a structure that is different from the uneven structure in the first region,
the second region in a plan view having a shape that forms at least one selected from the group consisting of characters, symbols, and graphics.

13-16. (canceled)

17. A display device comprising:
on a display surface, a transparent body including a surface with an uneven structure including protrusions, the width between the tops of any pair of the adjacent protrusions being equal to or shorter than visible light wavelengths,
the transparent body including a first region including a surface with the uneven structure and a second region including a surface with a structure that is different from the uneven structure in the first region,
the second region in a plan view having a shape that forms at least one selected from the group consisting of characters, symbols, and graphics.

18. The display device according to claim 17,
wherein the uneven structure in the first region and the structure in the second region are composed of a transparent resin.

19. The display device according to claim 17,
wherein the display device is a liquid crystal display device, a plasma display panel, or an organic electroluminescence display.

20. The display device according to claim 17,
wherein the second region is used as a logo and/or an advertisement when the display device is in an undisplayed state.
